(19) United States
(12) Patent Application Publication
(10) Pub. No.: US 2020/0184176 A1
(43) Pub. Date: Jun. 11, 2020

(54) ULTRASOUND FINGERPRINT DETECTION AND RELATED APPARATUS AND METHODS

(71) Applicants: Jianwei Liu, Fremont, CA (US); Keith G. Fife, Palo Alto, CA (US); Tyler S. Ralston, Clinton, CT (US)

(72) Inventors: Jianwei Liu, Fremont, CA (US); Keith G. Fife, Palo Alto, CA (US); Tyler S. Ralston, Clinton, CT (US)

(73) Assignee: Butterfly Network, Inc., Guilford, CT (US)

(21) Appl. No.: 16/705,444

(22) Filed: Dec. 6, 2019

Related U.S. Application Data
(60) Provisional application No. 62/777,027, filed on Dec. 7, 2018.

(51) Int. Cl. G06K 9/00; G06F 3/041; B06B 1/02; H01L 27/32

(52) U.S. Cl. CPC G06K 9/0002; G06F 3/0412; H01L 27/3234; H01L 27/323; B06B 1/0292

(57) ABSTRACT

An ultrasound fingerprint sensor is described. The ultrasound fingerprint sensor may incorporate capacitive ultrasound sensing technology, for example in the form of an array of capacitive ultrasonic transducers. The ultrasound fingerprint sensor may be incorporated into various electronic equipment, such as mobile electronic equipment in the form of smartphones and tablet computers, as well as in biometric sensing equipment, such as fingerprint access terminals.

### CROSS-REFERENCE TO RELATED APPLICATIONS

This application claims the benefit under 35 U.S.C. § 119(e) of U.S. Provisional Patent Application Ser. No. 62/777,027, filed Dec. 7, 2018 under Attorney Docket No. B1348.70090US00, and entitled “ULTRASOUND FINGERPRINT DETECTION AND RELATED APPARATUS AND METHODS,” which is hereby incorporated herein by reference in its entirety.

### BACKGROUND

### Field

The present application relates to ultrasound sensors.

### Related Art

Ultrasound systems may be used to perform diagnostic imaging and/or treatment, using sound waves with frequencies that are higher than those audible to humans. Ultrasound imaging may be used to see internal soft tissue body structures. When pulses of ultrasound are transmitted into tissue, sound waves are reflected off the tissue, with different tissues reflecting varying degrees of sound. These reflected sound waves may then be recorded and displayed as an ultrasound image to the operator. The strength (amplitude) of the sound signal and the time it takes for the wave to travel through the body provide information used to produce the ultrasound image. Different types of images can be formed using ultrasound systems. For example, images can be generated that show two-dimensional cross-sections of tissue, blood flow, motion of tissue over time, the location of blood, the presence of specific molecules, the stiffness of tissue, or the anatomy of a three-dimensional region.

Some ultrasound imaging devices may be fabricated using micromachined ultrasound transducers, including a flexible membrane suspended above a substrate. A cavity is located between part of the substrate and the membrane, such that the combination of the substrate, cavity and membrane form a variable capacitor. When actuated by an appropriate electrical signal, the membrane generates an ultrasound signal by vibration. In response to receiving an ultrasound signal, the membrane is caused to vibrate and, as a result, an output electrical signal can be generated.

### BRIEF SUMMARY

Aspects of the present application provide an ultrasound fingerprint sensor. The ultrasound fingerprint sensor may incorporate capacitive ultrasound sensing technology, for example in the form of an array of capacitive ultrasonic transducers. The ultrasound fingerprint sensor may be incorporated into various electronic equipment, such as mobile electronic equipment in the form of smartphones and tablet computers, as well as in biometric sensing equipment, such as fingerprint access terminals.

According to an aspect of the application, an ultrasound fingerprint sensing system is provided, comprising: a housing; a display coupled to the housing such that the display and housing define an internal area; and an ultrasound-on-a-chip device disposed in the internal area between the display and housing and comprising an array of capacitive ultrasonic transducers integrated with an integrated circuit, the array of capacitive ultrasonic transducers configured to emit and detect ultrasound signals through the display.

According to an aspect of the application, a mobile electronic device with fingerprint detection is provided, comprising: a housing; an ultrasound-on-a-chip device disposed within the housing; and a display coupled to the housing, wherein the ultrasound-on-a-chip device is disposed between the housing and the display and configured to receive reflected ultrasound signals from an object disposed on the display.

According to an aspect of the present application, an ultrasound fingerprint detector is provided, comprising: an ultrasound-on-a-chip component comprising capacitive ultrasonic transducers monolithically integrated with a complementary metal oxide semiconductor (CMOS) substrate having CMOS circuitry and configured to emit a beam with focus about ½ inch from the capacitive ultrasonic transducers; a display glass; and a housing coupled to the display glass and disposed such that the ultrasound-on-a-chip device is disposed between the housing and the display glass.

According to an aspect of the present application, an ultrasound fingerprint detection apparatus is provided, comprising: an ultrasound-on-a-chip device comprising an array of capacitive micromachined ultrasonic transducers (CMUTs) monolithically integrated with complementary metal oxide semiconductor (CMOS) circuitry; a processor coupled to the CMOS circuitry; and a memory coupled to the processor and configured to store a known fingerprint, wherein the processor is configured to receive data from the integrated circuitry indicative of a detected fingerprint and to compare the data to the known fingerprint.

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in all the figures in which they appear.

FIG. 1A illustrates an exploded view of a portable electronic device comprising a fingerprint sensor, according to a non-limiting embodiment of the present application.

FIG. 1B shows the assembled portable electronic device of FIG. 1A.

FIG. 2 illustrates a side view of an electronic device comprising an ultrasound fingerprint sensor scanning a finger, according to a non-limiting embodiment of the present application.

FIG. 3 illustrates a non-limiting internal cross-section of an electronic device comprising an ultrasound fingerprint sensor, according to a non-limiting embodiment of the present application.

FIG. 4A illustrates a non-limiting example of a capacitive ultrasonic transducer according to a non-limiting embodiment of the present application.

FIG. 4B illustrates a non-limiting example of an alternative capacitive ultrasonic transducer according to a non-limiting embodiment of the present application including an engineered substrate bonded with an integrated circuit substrate.

FIG. 4C illustrates a non-limiting example of an alternative capacitive ultrasonic transducer according to a non-limiting embodiment of the present application including a membrane bonded directly to an integrated circuit substrate.

FIG. 5 illustrates an array of capacitive ultrasonic transducers which may form an ultrasound fingerprint sensor according to a non-limiting embodiment of the present application.

FIG. 6 illustrates a non-limiting example of a circuit board including several electrical components in addition to an ultrasound fingerprint sensor comprising an ultrasound-on-a-chip device.

FIGS. 7A, 7B, 7C, and 7D illustrate alternative form factors of electronic devices incorporating an ultrasound fingerprint sensor according to non-limiting embodiments of the present application.

### DETAILED DESCRIPTION

Aspects of the present application provide an ultrasound fingerprint sensor. The ultrasound fingerprint sensor may incorporate capacitive ultrasound sensing technology, for example in the form of an array of capacitive ultrasonic transducers. The ultrasound fingerprint sensor may be incorporated into various electronic equipment, such as mobile electronic equipment in the form of smartphones and tablet computers, as well as in biometric sensing equipment, such as fingerprint access terminals.

According to aspects of the present application, an ultrasound fingerprint sensor comprises an ultrasound-on-a-chip device within a housing and configured to sense a fingerprint of a subject through a display. Various electronic equipment, such as smartphones, tablet computers, and automatic teller machines, include a display, which in at least some situations is touch-sensitive. According to an aspect of the present application, an ultrasound sensor may be contained within such equipment, and configured to detect a fingerprint of a user touching the display. Conventional ultrasound imaging devices use an acoustic impedance matching layer to contact a subject. However, in the case of electronic equipment such as those listed above, the materials of the equipment are typically selected for the purpose of functions other than fingerprint detection, such as display functions. For instance, cover glass is typically selected for a smartphone, covering a display layer which may include an organic light emitting diode (OLED) layer or other display material. The acoustic properties of such materials are not ideal for ultrasound transmission, as they can lead to undesirable or large reflections of ultrasound signals. Despite this, aspects of the present application provide ultrasound fingerprint sensors as part of electronic equipment having other functions (e.g., a phone) and configured to detect a fingerprint through a display layer.

It should be appreciated that the embodiments described herein may be implemented in any of numerous ways. Examples of specific implementations are provided below for illustrative purposes only. It should be appreciated that these embodiments and the features/capabilities provided may be used individually, all together, or in any combination of two or more, as aspects of the technology described herein are not limited in this respect.

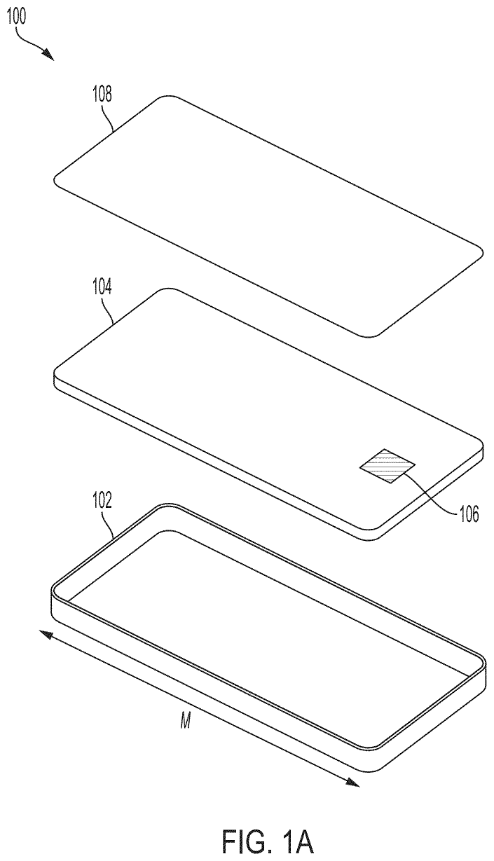

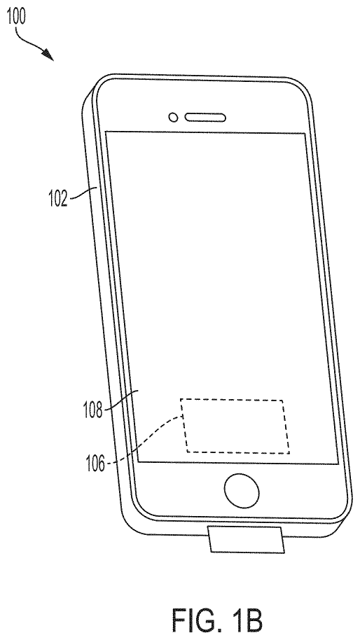

FIG. 1A illustrates an exploded view of a portable electronic device comprising a fingerprint sensor, according to a non-limiting embodiment of the present application. The portable electronic device 100 includes a housing 102, circuit board 104, ultrasound fingerprint sensor 106, and cover glass 108.

The portable electronic device 100 may be a cell phone, smartphone, or other portable electronic device. The portable electronic device 100 may be sized to be hand-held, for instance having a long dimension M of less than approximately six inches. The various aspects described herein are not limited by the particular dimensions. The portable electronic device may provide various functions, such as making and receiving phone calls, sending and receiving text messages, connecting to the Internet, word processing, speech recognition, or other functions.

The housing 102 is configured to house the circuit board 104. The circuit board 104 is a printed circuit board in some embodiments, although alternatives are possible. More generally, the circuit board 104 is one non-limiting example of a substrate which may be provided to support various components of the portable electronic device 100.

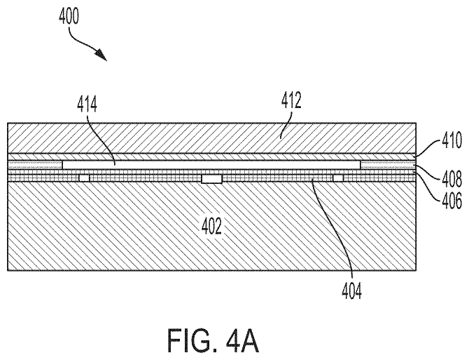

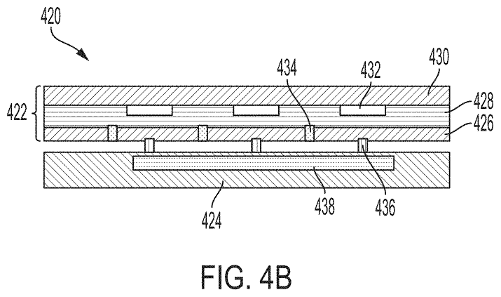

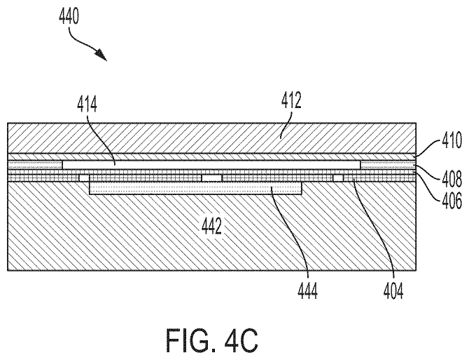

The ultrasound fingerprint sensor 106 may be a capacitive-based ultrasound fingerprint sensor. In some embodiments, the ultrasound fingerprint sensor is an ultrasound-on-a-chip device comprising an array of capacitive ultrasonic transducers integrated with integrated circuitry. In some embodiments, the ultrasound-on-a-chip device comprises an array of capacitive micromachined ultrasonic transducers (CMUTs) integrated with complementary metal oxide semiconductor (CMOS) circuitry. A non-limiting example is described further below in connection with FIGS. 4B and 4C. As shown in FIG. 1A, the ultrasound fingerprint sensor 106 may be a discrete packaged component coupled to the circuit board 104. Other configurations are possible, however, such as monolithically integrating the ultrasonic transducers of the ultrasound fingerprint sensor 106 with other components on a common substrate.

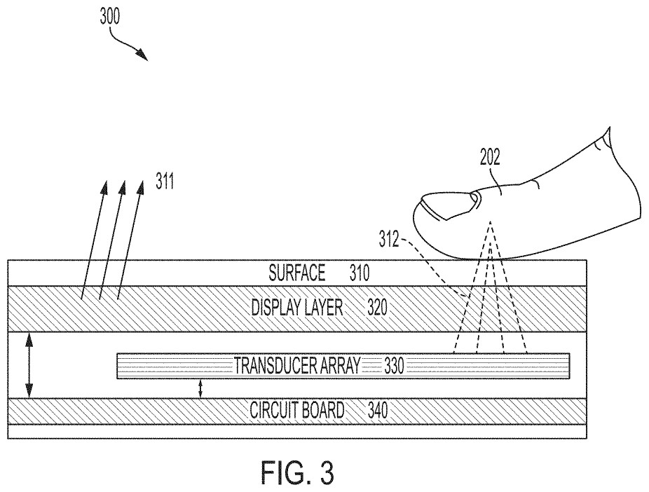

The cover glass 108 is configured to mate with the housing 102 and define an enclosed space in which the circuit board 104 is disposed. The cover glass 108 may simply be a layer of glass or plastic, or may be part of a display. For example, an organic display layer may be disposed on the backside of the cover glass 108, an example of which is shown in FIG. 3 and described further below.

The ultrasound fingerprint sensor 106 may be configured to emit and receive ultrasound signals through the cover glass 108. In this manner, the fingerprint of a subject touching the cover glass 108 may be detected. In some embodiments, the ultrasound fingerprint sensor 106 may be configured to emit and receive through glass, ceramic, metal, and organic film stacks, such as may be present in smartphones, tablet computers, and other electronic devices.

FIG. 1B shows the assembled portable electronic device of FIG. 1A. In this figure the ultrasound fingerprint sensor 106 is illustrated as a dashed box since it is not visible through the cover glass 108. The ultrasound fingerprint sensor 106 is disposed within an enclosed space defined by the housing 102 and the cover glass 108.

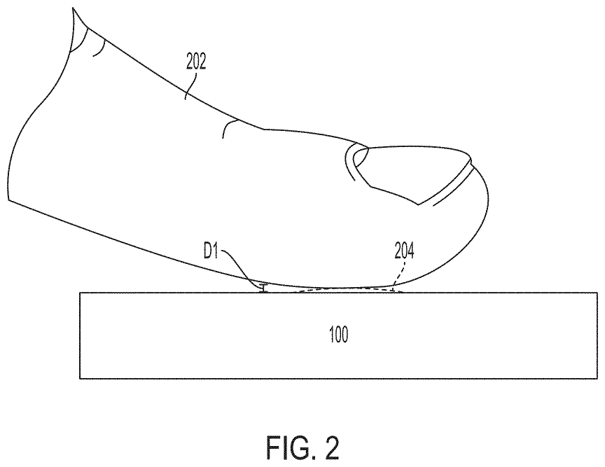

FIG. 2 illustrates a side view of an electronic device comprising an ultrasound fingerprint sensor scanning a finger 202, according to a non-limiting embodiment of the present application. FIG. 2 depicts an example of an ultrasound beam 204 extending from an ultrasound fingerprint sensor by a distance D1 toward a subject's finger. The ultrasound fingerprint sensor may in some cases comprise a capacitive micromachined ultrasonic transducer (CMUT), and in some cases may comprise an array of CMUTs which together sense a target. For example, as previously described, the ultrasound fingerprint sensor may be an ultrasound-on-a-chip device comprising an array of capacitive ultrasonic transducers. The value of distance D1 may be small, and in some embodiments may be zero, meaning that the finger 202 is in direct contact with the portable electronic device 100, such as with the cover glass 108. For purposes of illustration, however, the distance D1 is shown as non-zero. The ultrasound beam 204 may be of a frequency configured to reflect from the surface of the finger 202. In this manner, an image of the fingerprint may be generated. According to some embodiments, the ultrasound beam may be focused within one-half of an inch of the ultrasound fingerprint sensor. For instance, a distance from an upper surface of a CMUT (or array of CMUTs) to a focus point of the beam 204 may be less than one-half of an inch. In some embodiments, the ultrasound fingerprint sensor may be configured to focus an ultrasound beam substantially at the surface of the display of an electronic device within which the ultrasound fingerprint sensor is disposed. For example, the ultrasound beam may be focused within 0.5 mm to 5 mm of an exterior surface of a display glass of the electronic device. In some embodiments, the focus of the beam may be optimized to be at a desired location, such as at the exterior surface of a display, by correcting for anticipated signal delays introduced by the display. In some embodiments, the ultrasound beam 204 may be electronically scanned, and therefore is not a static beam. The electronic scanning may be controlled by circuitry within the fingerprint sensor, such as CMOS circuitry of an ultrasound-on-a-chip device.

FIG. 3 illustrates a non-limiting internal cross-section of an electronic device comprising an ultrasound fingerprint sensor, according to a non-limiting embodiment of the present application. In the example of FIG. 3, the electronic device 300 comprises a circuit board 340 electrically coupled to, and configured to control, a display layer 320 and an ultrasound transducer array 330. The display layer is configured to produce light 311 through a surface 310 which may for instance comprise glass or transparent plastic. The display layer 320 may comprise a light emitting diode (LED) display or an organic light emitting diode (OLED) display, as non-limiting examples. The ultrasound transducer array 330 is configured to sense a subject's finger 202 by emitting ultrasound signals 312. Ultrasound transducer array 330 may comprise any number of capacitive ultrasonic transducers arranged in a layer. In some embodiments, the ultrasonic transducer array 330 may be part of an ultrasound-on-a-chip device, with integrated circuitry integrated with the capacitive ultrasonic transducers. An example is described further below in connection with FIGS. 4B and 4C.

It should be appreciated that the electronic device 300 of FIG. 3 may include additional components not illustrated. For example, the circuit board 340 may include a processor, memory, microphone, speaker, camera, display driver, or other components. Thus, the electronic device 300 may perform functions other than fingerprint detection. In fact, the electronic device 300 may, in some embodiments, be primarily used for functions other than fingerprint detection. The fingerprint detection functionality may be used, for example, to provide user access to the electronic device to access additional functions, such as those described previously herein.

As has been described herein, aspects of the present application provide a capacitive sensing ultrasound fingerprint sensor. In some embodiments, capacitive micromachined ultrasonic transducers may be employed. Various configurations of capacitive transducers and control and processing circuitry may be employed. Three non-limiting examples include: (a) an array of capacitive micromachined ultrasonic transducers disposed on a semiconductor substrate separate from control and processing circuitry; (b) an array of capacitive micromachined ultrasonic transducers formed by an engineered substrate integrated with a circuit substrate; and (c) an array of capacitive micromachined ultrasonic transducers directly integrated on a circuit substrate through low temperature wafer bonding of a membrane layer on the integrated circuit substrate. Each of these examples is now described.

FIG. 4A illustrates a non-limiting example of a micromachined capacitive ultrasonic transducer as may be used in an ultrasound fingerprint sensor, according to an embodiment of the present application. As will be described further below, the illustrated transducer does not include control or processing circuitry. Thus, an array of such transducers on one semiconductor chip may be coupled to a separate chip or circuit board having suitable control and/or processing circuitry.

The capacitive micromachined ultrasonic transducer 400 comprises a substrate 402, electrode 404, dielectric layers, 406, 408, and 410, and silicon layer 412. The combination of the dielectric layer 410 and silicon layer 412 may serve as a membrane above the cavity 414. The silicon layer 412 may be doped suitably to be conducting, or an optional further electrode layer may be disposed on the silicon layer 412. Thus, the combination of the membrane, cavity, and electrode 404 may form a variable capacitor, with the capacitance depending on the distance between the membrane and the electrode.

The substrate 402 may be any suitable substrate. For example, the substrate 402 may be a semiconductor substrate, formed of silicon or other suitable semiconductor material. As described previously, while the substrate 402 may include the electrode 404 and electrical routing layers, it may lack control circuitry and processing circuitry for controlling operation of the capacitive micromachined ultrasonic transducer and processing output signals from the capacitive micromachined ultrasonic transducer. Instead, such circuitry may be provided off-chip.

The electrode 404 may be any material, shape, and dimensions for providing desired electrical behavior, including applying a voltage and receiving a signal resulting from vibration of the membrane. In some embodiments, the electrode 404 may be a ring, and thus may appear in cross-section as shown in FIG. 4A. However, other shapes are possible. The electrode may be formed of a metal or other suitable conducting material.

The dielectric layers 406, 408, and 410 may be any suitable materials for providing dielectric behavior. As a non-limiting example, dielectric layer 406 may be aluminum oxide (Al₂O₃), and dielectric layers 408 and 410 may be silicon oxide.

The silicon layer 412 may have any suitable thickness for serving as a membrane, or part of a membrane in combination with the dielectric layer 410. For example, the membrane, including the silicon layer 412, may have a thickness less than 50 microns in some embodiments.

As described above, an alternative implementation of a capacitive micromachined ultrasonic transducer is to form the transducer as part of an engineered substrate which is bonded to an integrated circuit substrate. The integrated circuit substrate may include integrated circuitry representing control circuitry and/or processing circuitry. FIG. 4B illustrates a non-limiting example. Specifically, FIG. 4B is a cross-sectional view of a plurality of capacitive ultrasonic transducers including a circuit substrate integrated with an engineered substrate having sealed cavities, according to a non-limiting embodiment of the present application.

The capacitive ultrasonic transducers 420 include an engineered substrate 422 and circuit substrate 424. The engineered substrate 422 includes a first silicon layer 426, a dielectric layer 428, and a second silicon layer 430 representing a membrane. Cavities 432 are positioned between the dielectric layer 428 and the second silicon layer 430. The cavities are sealed by the second silicon layer 430 in this non-limiting example. The engineered substrate 422 further comprises insulating portions 434 providing electrical insulation between conductive portions of the first silicon layer 426.

The circuit substrate 424 includes integrated circuitry 438. The integrated circuitry 438 may include control and/or processing circuitry for controlling operation of the ultrasonic transducers of the engineered substrate and/or for processing signals output from the ultrasonic transducers. In some embodiments, the integrated circuitry 438 is CMOS circuitry and the circuit substrate 424 is a CMOS substrate. The integrated circuitry may include a receive beamformer, configured to perform receive beamforming. The integrated circuitry may control the ultrasonic transducers to emit and receive in a manner such that for a single transmit event, multiple transducers may emit and receive ultrasound signals. In some embodiments, multi-channel emission and reception may be performed as part of a given transmit event, providing greater data than single-channel transmission and reception would. In the context of fingerprint detection, multi-channel operation for a given a transmit event may facilitate correction of aberrations or other undesirable effects in the data. In some embodiments, the circuitry may include multiplexing circuitry. In some embodiments, multiplexing circuitry configured to multiplex transmission or reception of multiple channels may be provided.

The engineered substrate 422 and the circuit substrate 424 are bonded together by bonds 436. In some embodiments, the bonds 436 may be conductive, providing electrical connection between the engineered substrate and the integrated circuitry 438.

The capacitive ultrasonic transducers 420 may be formed using two wafer-level bonding steps. The engineered substrate 422 may be formed by bonding a first silicon wafer with a second silicon wafer, and then annealing at high temperature to form a strong bond. The anneal temperature may be above 450° C. in some embodiments. The engineered substrate may subsequently be bonded with the circuit substrate 424 at a temperature sufficiently low to ensure that the integrated circuitry 438 is not damaged during the bonding.

Further examples of capacitive micromachined ultrasonic transducers formed in an engineered substrate and bonded with a circuit substrate are described in U.S. Pat. Publication No. 2018/0257927 A1, which is hereby incorporated herein by reference in its entirety.

An alternative implementation of a capacitive micromachined ultrasonic transducer is to form the transducer directly on an integrated circuit substrate by bonding the membrane of the transducer directly to the integrated circuit substrate. FIG. 4C illustrates a non-limiting example. As shown, the structure of the capacitive ultrasonic transducer 440 of FIG. 4C is substantially the same as that of the capacitive ultrasonic transducer 400 of FIG. 4A, except that the substrate 402 is replaced with a circuit substrate 442 including integrated circuitry 444. The integrated circuitry 444 may be substantially the same as integrated circuitry 438 of FIG. 4B, and may perform the same functions in some embodiments.

The capacitive ultrasonic transducer 440 of FIG. 4C may be fabricated using low temperature wafer bonding. The structures of the circuit substrate 442 may be fabricated, including the cavity 414, after which a wafer comprising dielectric layer 410 and silicon layer 412 may be bonded with the circuit substrate to seal the cavity 414. The bonding may be performed at a temperature sufficiently low to ensure that the integrated circuitry 444 is not damaged. For example, the bonding may be performed without using temperatures above 450° C. in some embodiments.

Further examples of capacitive micromachined ultrasonic transducers integrated with an integrated circuitry substrate, and having a membrane bonded directly with the integrated circuit substrate, are described in U.S. Pat. No. 9,242,275, which is incorporated herein by reference in its entirety.

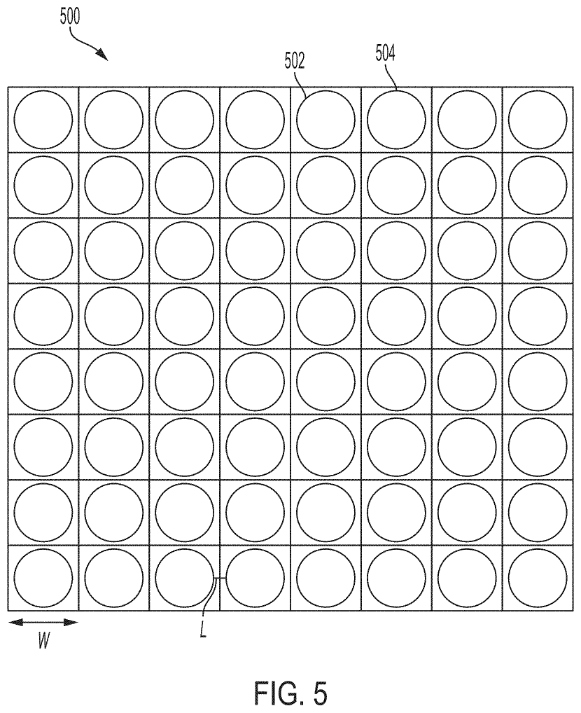

According to an aspect of the present application, an ultrasound fingerprint sensor employs an array of capacitive micromachined ultrasonic transducers. For example, an array of the types of transducers shown in FIGS. 4A-4C may be provided. FIG. 5 illustrates a non-limiting example.

FIG. 5 illustrates a top view of a two-dimensional array of micromachined ultrasonic transducers 500. The ultrasonic transducers may be any of the types previously described in connection with FIGS. 4A-4C, although other forms of capacitive ultrasonic transducers may be used. In the illustrated example, the ultrasonic transducers 502 are circular and separated into transducer cells 504. The cells may have a width W (which in the case of circular cross-section cells may be a diameter) between 10 microns and 100 microns, between 25 microns and 100 microns, between 50 microns and 75 microns, or any other suitable dimensions for providing a resolution sufficient to detect features of a fingerprint. The ultrasonic transducers 502 may be spaced by a distance L, which may be between 1 micron and 20 microns. The cell membrane may have a thickness (into and out of the page) between 1 micron and 20 microns in some embodiments, and between 1 micron and 5 microns in other embodiments. The transducers may have a pitch of any suitable value, such as within the range of the values of W described previously. The ultrasonic transducers may have dimensions sufficient to operate at frequencies between 1 MHz and 50 MHz, between 5 MHz and 80 MHz, for example between 5 MHz and 30 MHz, or any other frequency or range of frequencies within these ranges. As shown, the transducers may be arranged in a two-dimensional array in some embodiments, although alternatives are possible. When arranged in a two-dimensional array, the array may have any suitable number of transducers along the rows and columns. In some embodiments, the array may have an equal number of transducers in rows and columns, however alternatives are possible. According to embodiments of the present application, the ultrasonic transducers may transmit and/or receive ultrasound signals of frequencies assuming any value or range of values within those ranges listed above.

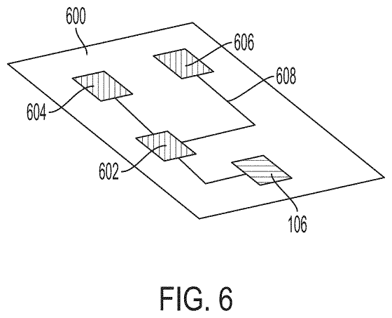

FIG. 6 illustrates a non-limiting example of a circuit board including several electrical components in addition to an ultrasound fingerprint sensor comprising an ultrasound-on-a-chip device. The circuit board 600 includes the ultrasound fingerprint sensor 106, processor 602, memory 604, and display driver 606. Each of the ultrasound fingerprint sensor 106, processor 602, memory 604, and display driver 606 may be discrete components interconnected as shown by conductive traces 608. Other components may be included as well, as FIG. 6 is a non-limiting example of the types of components which may be included in electronic equipment incorporating an ultrasound fingerprint sensor, such as a smartphone, tablet computer, or smartwatch.

According to a non-limiting embodiment, the ultrasound fingerprint sensor 106 may communicate with the processor 602 and memory 604 to perform fingerprint detection. The memory 604 may store one or more known fingerprints. The ultrasound fingerprint sensor 106 may detect a fingerprint and provide the detected fingerprint to the processor 602. The processor 602 may retrieve from the memory 604 one or more known fingerprints and compare the detected fingerprint to the retrieved fingerprint(s). If the detected fingerprint matches a known fingerprint, the processor 602 may grant the user access to additional functionality of the device or system incorporating the circuit board 600. If no match is determined, further access may be rejected. This manner of operation is a non-limiting example, as alternatives are possible.

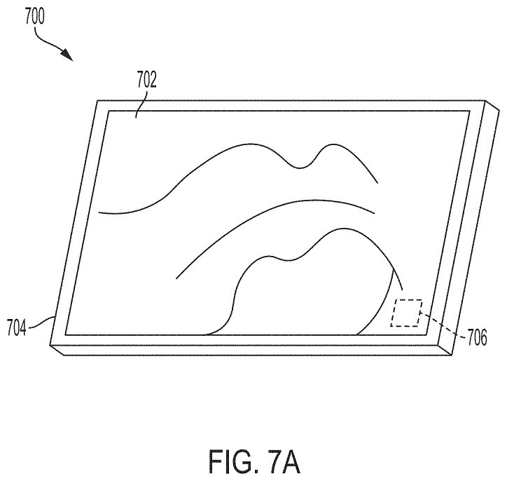

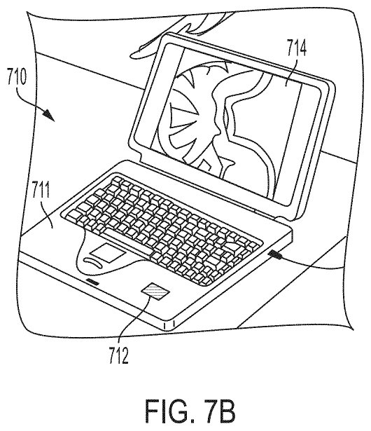

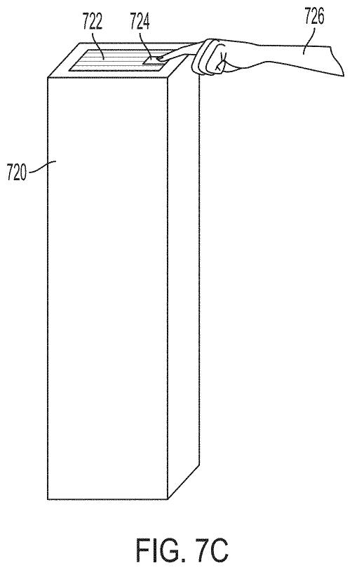

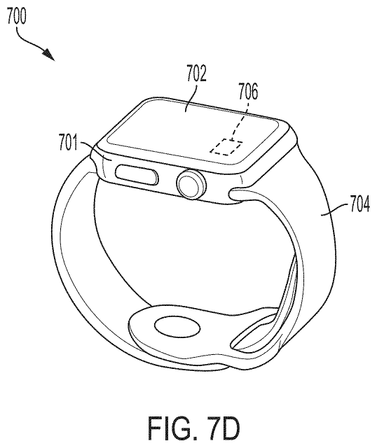

FIG. 7A-7D illustrate non-limiting examples of electronic devices which may include ultrasound fingerprint sensors of the types described herein, according to non-limiting embodiments of the present application. These examples are in addition to the example illustrated in FIG. 1B.

FIG. 7A illustrates a tablet computer 700 having a display 702, housing 704, and ultrasound fingerprint sensor 706. The ultrasound fingerprint sensor may be disposed between the display 702 and housing 704, and thus in some embodiments is disposed within a closed space between those two components. For this reason, the ultrasound fingerprint sensor may be visually obscured by the display 702, and thus is shown as a dashed box. The display 702 may be any of the types previously described herein, or any other suitable type. For example, the display 702 may include a display layer—for example, an OLED layer—and a cover glass. Alternatives are possible. The ultrasound fingerprint sensor 706 may be used to provide access to additional functions of the tablet computer 700, such as to critical data, word processing, Internet access, and camera functionality, among other possible functions. The positioning of the ultrasound fingerprint sensor 706 is non-limiting, as it may be positioned at any suitable location for detecting the fingerprint of a user through the display.

FIG. 7B illustrates a laptop computer 710 having a housing 711, an ultrasound fingerprint sensor 712, and a display 714. In this example, the ultrasound fingerprint sensor 712 is not disposed under the display of the electronic device, but rather is disposed underneath a portion of the housing that may not be used for display. The ultrasound fingerprint sensor 712, which may be any of the types of ultrasound fingerprint sensors described herein, may be used to provide access to other functionality of the laptop computer.

FIG. 7C illustrates an example of a security access terminal incorporating an ultrasound fingerprint sensor according to an aspect of the present application. The security access terminal 720 includes a cover glass 722 and ultrasound fingerprint sensor 724, which may be disposed beneath the cover glass. Optionally, the cover glass 722 may be part of a display. However, in alternative embodiments, the security access terminal 720 may simply provide a fingerprint detection function, without display of other types of content. For example, the user 726 may scan his/her fingerprint on the ultrasound fingerprint sensor 724 to gain access to a building, room, or other secure location. Other uses of security access terminals are also possible.

FIG. 7D illustrates a wearable electronic device comprising an ultrasound fingerprint sensor, according to a non-limiting embodiment of the present application. The smartwatch 700 includes a housing 701, display 702, wristband 704, and ultrasound fingerprint sensor 706. The ultrasound fingerprint sensor 706 may be any of the types of ultrasound fingerprint sensors described previously herein. The ultrasound fingerprint sensor 706 may be disposed between the housing 701 and display 702, and thus is indicated by a dashed box. A user may scan his or her fingerprint to gain access to other functions of the watch.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

As used herein, reference to a numerical value being between two endpoints should be understood to encompass the situation in which the numerical value can assume either of the endpoints. For example, stating that a characteristic has a value between A and B, or between approximately A and B, should be understood to mean that the indicated range is inclusive of the endpoints A and B unless otherwise noted.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

Having described above several aspects of at least one embodiment, it is to be appreciated various alterations, modifications, and improvements will readily occur to those skilled in the art. Such alterations, modifications, and improvements are intended to be object of this disclosure. Accordingly, the foregoing description and drawings are by way of example only.

What is claimed is:

1. An ultrasound fingerprint sensing system, comprising:
a housing;
a display coupled to the housing such that the display and housing define an internal area; and
an ultrasound-on-a-chip device disposed in the internal area between the display and housing and comprising an array of capacitive ultrasonic transducers integrated with an integrated circuit, the array of capacitive ultrasonic transducers configured to emit and detect ultrasound signals through the display.

2. The ultrasound fingerprint sensing system of claim 1, wherein the display is a touch-sensitive display.

3. The ultrasound fingerprint sensing system of claim 1, wherein the display comprises an organic light emitting diode (OLED) display layer and cover glass.

4. The ultrasound fingerprint sensing system of claim 1, wherein the housing is a hand-held housing.

5. The ultrasound fingerprint sensing system of claim 1, wherein the array of capacitive ultrasonic transducers is disposed in an engineered substrate and the integrated circuit is disposed in a circuit substrate bonded with the engineered substrate.

6. The ultrasound fingerprint sensing system of claim 1, wherein the integrated circuit is disposed in a complementary metal oxide semiconductor (CMOS) substrate and the array of capacitive ultrasonic transducers comprises a membrane bonded to the CMOS substrate.

7. The ultrasound fingerprint sensing system of claim 1, wherein the ultrasound-on-a-chip device is configured to focus emitted ultrasound signals approximately at a surface of the display.

8. The ultrasound fingerprint sensing system of claim 1, further comprising a memory disposed in the internal area between the display and housing and coupled to the ultrasound-on-a-chip device.

9. A portable electronic device comprising the ultrasound fingerprint sensing system of claim 1.

10. The portable electronic device of claim 9, wherein the portable electronic device is a smartphone.

11. The ultrasound fingerprint sensing system of claim 1, wherein the array of capacitive ultrasonic transducers is configured to emit and detect ultrasound signals in a frequency range of 5 MHz-30 MHz.

12. The ultrasound fingerprint sensing system of claim 1, wherein the array of capacitive ultrasonic transducers comprises a plurality of ultrasonic transducers having cavity widths between 25 microns and 100 microns.

13. The ultrasound fingerprint sensing system of claim 1, wherein the array of capacitive ultrasonic transducers is a two-dimensional array.

14. The ultrasound fingerprint sensing system of claim 1, wherein the integrated circuitry is configured to control the ultrasound signals to perform an electronic scan.

15. A mobile electronic device with fingerprint detection, comprising:
a housing;
an ultrasound-on-a-chip device disposed within the housing; and
a display coupled to the housing, wherein the ultrasound-on-a-chip device is disposed between the housing and the display and configured to receive reflected ultrasound signals from an object disposed on the display.

16. The mobile electronic device of claim 15, wherein the housing has a longest dimension less than approximately six inches.

17. The mobile electronic device of claim 15, wherein the display comprises a light emitting display layer and a glass layer.

18. The mobile electronic device of claim 15, wherein the ultrasound-on-a-chip device comprises an array of capacitive ultrasonic transducers disposed in an engineered substrate and an integrated circuit disposed in a circuit substrate bonded with the engineered substrate.

19. The mobile electronic device of claim 15, wherein the ultrasound-on-a-chip device comprises an integrated circuit disposed in a complementary metal oxide semiconductor (CMOS) substrate and an array of capacitive ultrasonic transducers having a membrane bonded to the CMOS substrate.

20. The mobile electronic device of claim 19, wherein the mobile electronic device is a smartwatch.

21. The mobile electronic device of claim 19, wherein the mobile electronic device is a smartphone.

22. The mobile electronic device of claim 18, wherein the array of capacitive ultrasonic transducers is configured to emit and detect ultrasound signals in a frequency range of 5 MHz-30 MHz.

23. The mobile electronic device of claim 18, wherein the array of capacitive ultrasonic transducers comprises a plurality of ultrasonic transducers having cavity widths between 25 microns and 100 microns.

24. The mobile electronic device of claim 15, further comprising a circuit board comprising a plurality of discrete electronic components disposed thereon, wherein the ultrasound-on-a-chip device is disposed on the circuit board and in electrical communication with a first electronic component of the plurality of discrete electronic components.
